(19) United States
(12) Patent Application Publication
(10) Pub. No.: US 2006/0182874 A1
(43) Pub. Date: Aug. 17, 2006

(54) Method of preparing an apparatus for positioning a molecule

(76) Inventor: Tan N. Ha, Fremont, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/060,661

(22) Filed: Feb. 17, 2005

(51) Int. Cl. C23C 16/00; C23C 16/52

(52) U.S. Cl. 427/8; 427/248.1; 118/726

(57) ABSTRACT

The present invention provides a method of preparing an apparatus for positioning a molecule between at least two surfaces of the apparatus. The method includes depositing a material on at least one of the surfaces which are spaced apart by a distance. The method also includes controlling the distance by controlling an amount of the deposited material so that the distance approximates a dimension of the molecule.

### FIELD OF THE INVENTION

The present invention relates generally molecular electronics and more particularly to a method of preparing an apparatus for positioning a molecule.

### BACKGROUND OF THE INVENTION

It is now recognised that performance increase and miniaturisation of electronic devices are not unlimited. A limit is reached when the size of device elements is so small that quantum physics effects become apparent and the device does not operate in a manner that is expected from classical physics.

Alternative technologies are being considered to enable fabrication of new devices and the field of molecular electronics is one field that is of particular interest. Selected types of molecules may be used as switches and have a size that is much smaller than that of conventional switches.

Research is presently in progress to characterize electrical properties of such molecules for electronic applications. Typically a molecule suspended between two opposing wire tips and the molecule is in electrical communication with the wires via tunnelling junctions.

Using conventional mechanical methods, it is very difficult to position the tips precisely so that they define a gap which is suitable for positioning and contacting the molecule. However, even the best mechanical manipulators, which may include piezoelectric drives, often do not allow movement of the tips relative to each other in a manner that is accurate on a molecular level. Accordingly, there is a need for technological advancement.

### SUMMARY OF THE INVENTION

Briefly, an embodiment of the present invention provides a method of preparing an apparatus for positioning a molecule between at least two surfaces of the apparatus. The method includes depositing a material on at least one of the surfaces which are spaced apart by a distance. The method also includes controlling the distance by controlling an amount of the deposited material so that the distance approximates a dimension of the molecule.

The invention will be more fully understood from the following description of embodiments of the invention. The description is provided with reference to the accompanying drawings.

### BRIEF DESCRIPTION OF THE DRAWINGS

FIG. 1 is a flow chart illustrating a method of preparing an apparatus for positioning a molecule according to an embodiment of the present invention;

FIGS. 2 is a schematic cross-sectional representation of an apparatus for testing a molecule according to an embodiment of the present invention; and

FIG. 3 is a flow chart illustrating a method of fabricating a molecular electronics device according to an embodiment of the present invention.

### DETAILED DESCRIPTION OF EMBODIMENTS

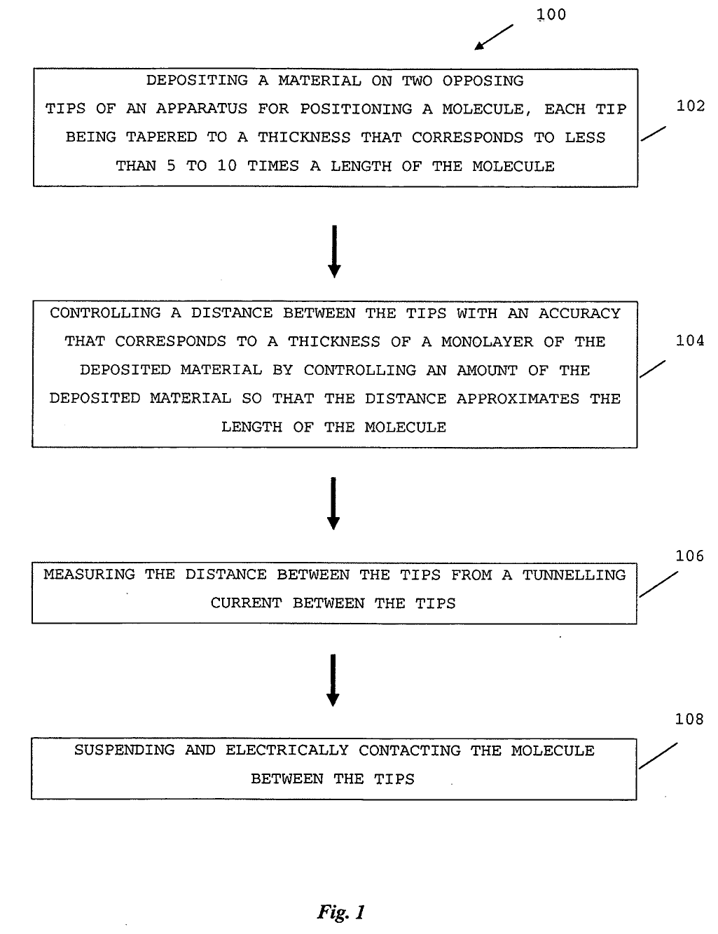

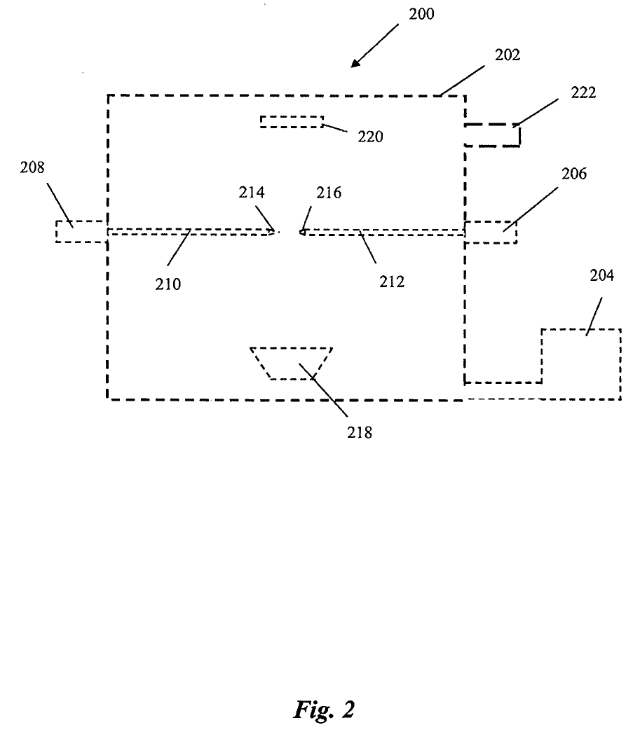

Referring initially to FIGS. 1 and 2, a method of preparing an apparatus for positioning a molecule between at least two surfaces of the apparatus and an apparatus for testing a molecule are now described. It is to be appreciated that the meaning of the term “molecule” includes molecular units that may have one or more than one single molecule. For example, a chain of molecules together also forms a molecule and will herein be referred to as such.

FIG. 1 shows a flow chart of the method 100 of preparing an apparatus for positioning a molecule between two surfaces of the apparatus. In this embodiment two surfaces are provided in the form of opposing tips. Each tip is tapered to a thickness that corresponds to less than 5-10 times a length of the molecule.

A material is deposited on the tips so that the distance between the tips decreases (step 102). In this embodiment, depositing of the material is performed with an accuracy that corresponds to the thickness of a mono-layer of the deposited material. In this case, it is possible to control the distance between the tips with the same accuracy which is of significant advantage. In this embodiment, the tips are pre-positioned and the amount of the material that is deposited on the tips is selected so that the distance between the tips approximates the length of the molecule (step 104).

Step 106 measures the distance between the tips by applying a voltage across the gap between the tips and measuring a tunnelling current. From the geometry of the tips and the magnitude of the tunnelling current a person skilled in the art can calculate the distance between the tips. Once the distance has a predetermined value that approximates the length of the molecule, the molecule is positioned between the tips and typically is suspended and electrically contacted by the tips (step 108). The molecule can then be electrically characterised by applying suitable voltages across the molecule and measuring a response from the molecule, such as a switching response. For example, the molecule may be a molecule of the Rotaxane or Catenane class of molecules.

The method 100 has the advantage in that the distance between the tips can be controlled by controlling the amount of the deposited material. If the amount of the deposited material is controlled with high accuracy, such as an accuracy that corresponds to a mono-layer of the deposited material, the distance between the tips can also be controlled with that accuracy without the need for further mechanical adjustments of the tip position relative to each other.

The tips typically are positioned in an evacuated chamber. The material that is deposited on the tips may originate from any suitable source. Any suitable physical or chemical vapour deposition method, including for example thermal evaporation and chemical vapour deposition, may be used to deposit the material.

The amount of the deposited material may be monitored using a film thickness monitor such as a quartz film thickness monitor which includes a vibrating quartz crystal and the amount of deposited material on the vibrating quartz crystal can be calculated from a frequency of the vibrations. A person skilled in the art can then estimate how much material is deposited on the tips. Further, it is to be appreciated that any other known method with which an amount of deposited material can be estimated may be used.

While in this embodiment the molecule is positioned between two opposing tips, in variations of this embodiment the molecule may be positioned between any number of tips. Further, it is to be appreciated that the surfaces between the molecule is positioned may not be tapered or tip-shaped but may have any other suitable form such as a rounded form. In addition, material may only be deposited on one of the tips.

The material that is deposited typically is an electrically conducting material such as a metallic material. However, it is to be appreciated that other materials, such as semi-conducting materials may also be used.

For positioning of the molecule between the tips a solution is then evaporated in the evacuated chamber. The solution includes sample molecules which diffuse between the tips. As the tips on which the material was deposited are separated by a distance that approximated at the length of a sample molecule, a sample molecule when diffused between the tips, will form chemical bondings with molecules of the tips.

FIG. 2 shows an apparatus 200 for testing a molecule. The apparatus 200 includes a vacuum chamber 202 which is evacuated by vacuum pump 204. The apparatus 200 also includes two manipulators 206 and 208 to which wires 210 and 212 are attached. The wires have tips 214 and 216 which are opposing and which can be moved relative to each other. In this embodiment the tips 214 and 216 are tapered to a thickness that approximates a length of the molecule. For example, such sharp tips may be fabricated by stretching a gold wire until the wire breaks.

The apparatus also includes a material source 218. The material source 218 may be any physical or chemical vapour deposition source. For example, a physical vapour may be generated by thermally heating a material so that it evaporates. Alternatively the material source 218 may be an electron beam evaporator, an ac or dc sputtering source, a molecular beam epitaxy source, any type of Knudsen cell, or a chemical vapour deposition source. The apparatus 200 also includes a film thickness monitor 220, in this case a quartz film thickness monitor, with which the amount of the deposited material can be measured.

The apparatus also includes a micro-dispenser 222 for dispensing a solution containing sample molecules which diffuse between the tips as described in the context of method 100. After a molecule has diffused between the tips the tips 214 and 216, electrical voltages may be applied across the molecule for testing a response from the molecule.

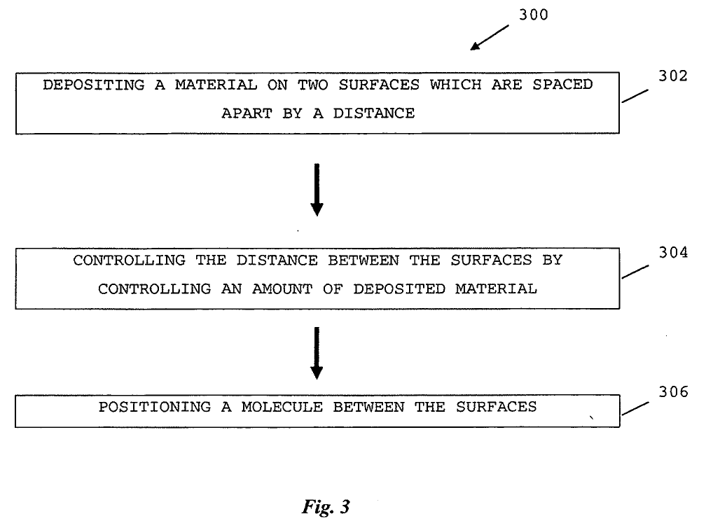

FIG. 3 illustrates a method of fabricating a molecular electronics device. The method 300 includes a first step 302 of depositing a material on two surfaces which are spaced apart by a distance. For example, the two surfaces may be opposing surfaces of adjacent contacts of a nano-scale structure for contacting molecules. Material is then deposited on surfaces of the contacts so as to control and fine-tune the distance between the contacts in a manner so that a molecule can be suspended and electrically contacted between the contacts (step 304).

Finally, step 306 positions molecules between the contacts in the manner as described above in the context of method 100. Using the method 300 molecules may be incorporated between the contacts to form a molecular electronics device. For example, an array of such contacts may be provided and respective molecules may be positioned in gaps between respective contacts.

It is to be appreciated that the embodiment illustrated in FIG. 3 and described above is not limited to fabricating a device having contacts between which molecules are positioned. Dependent on the device structure, molecules may be positioned between any other elements of the device structure.

Although the embodiments have been described with reference to particular examples, it is to be appreciated by those skilled in the art that the embodiments may take other forms. For example, the molecule may not necessarily be electrically connected but may simply be suspended between two or more surfaces. Further, material may not necessarily be positioned in a vacuum environment. In variations of the embodiments described, a solution may be used to deposit material on surfaces, such as the surfaces of opposing tips, and an amount of the material deposited on the tips may be controlled electrolytically. The amount of the material deposited on the tips may be used to control a distance between the tips in the solution. Further, molecules may be suspended in a solution and may be incorporated between the surfaces by diffusion.

What claimed is:

1. A method of preparing an apparatus for positioning a molecule between at least two surfaces of the apparatus, the method comprising:
depositing a material on at least one of the surfaces which are spaced apart by a distance; and
controlling the distance by controlling an amount of the deposited material so that the distance approximates a dimension of the molecule.

2. The method of claim 1 wherein:
the at least two surfaces are tip-shaped, each being tapered to a thickness that corresponds to less than 10 times a length of the molecule.

3. The method of claim 1 wherein:
the at least two surfaces are tip-shaped, each being tapered to a thickness that corresponds to less than 5 times a length of the molecule.

4. The method of claim 1 wherein:
the material is deposited so that the distance between the at least two surfaces is controlled with an accuracy that corresponds to a thickness of a monolayer of the deposited material.

5. The method of claim 1 wherein:
the material is deposited on the at least two surfaces.

7. The method of claim in claim 1 wherein:
the at least two surfaces are opposing.

8. The method of claim 1 wherein:
depositing the material comprises at least one of chemical vapour deposition and physical vapour deposition.

9. The method of claim 1 comprising:
suspending a molecule between the at least two surfaces.

10. The method of claim 1 comprising:
electrically contacting a molecule by the at least two surfaces.

11. The method of claim 1 comprising:
measuring a distance between the at least two surfaces from a tunnelling current between the first and the second surface.

12. A method of fabricating a molecular electronics device, comprising:
depositing a material on at least one of the at least two surfaces which are spaced apart by a distance;
controlling the distance between the at least two surfaces by controlling an amount of the deposited material so that the distance approximates a dimension of the molecule; and
positioning a molecule between the at least two surfaces.

13. An apparatus for testing a molecule, the apparatus comprising:
a chamber that can be evacuated;
a holder for the molecule, the holder being positioned in the chamber and having at least two spaced apart surfaces for positioning the molecule between the at least two spaced apart surfaces; and
a source of material flux for depositing material on at least one of the spaced apart surfaces and thereby controlling the distance between the spaced apart surfaces so that the distance approximates a dimension of the molecule.
